(19) United States
(12) Patent Application Publication
(10) Pub. No.: US 2025/0257462 A1
(43) Pub. Date: Aug. 14, 2025

(54) METHOD OF TREATING THIN FILMS AND METHOD OF MANUFACTURING MEMORY DEVICE

(71) Applicant: EGTM Co., Ltd., Suwon-si (KR)

(72) Inventors: Kyu Ho CHO, Suwon-si (KR); Ha Na KIM, Suwon-si (KR); Hyun Ju JUNG, Suwon-si (KR); Ju Hwan JEONG, Suwon-si (KR); Hyeon Sik CHO, Suwon-si (KR); Sun Young BAIK, Suwon-si (KR); Tae Young LEE, Suwon-si (KR); Shin Beom KIM, Suwon-si (KR)

(73) Assignee: EGTM Co., Ltd., Suwon-si (KR)

(21) Appl. No.: 19/048,776

(22) Filed: Feb. 7, 2025

(30) Foreign Application Priority Data
Feb. 8, 2024 (KR) 10-2024-0020025

(51) Int. Cl. C23C 16/455; C23C 16/40; C23C 16/44

(52) U.S. Cl. CPC C23C 16/45553; C23C 16/405; C23C 16/4408

(57) ABSTRACT

Disclosed is a method of depositing thin films, the method comprising supplying a metal precursor to the inside of a chamber where a substrate is placed to adsorb the metal precursor onto the substrate; purging the inside of the chamber; supplying a reactant to the inside of the chamber to react with the adsorbed metal precursor and form a thin film, wherein the metal precursor includes one or more halogen groups and one or more organic ligands.

### TECHNICAL FIELD

The present invention relates to a method of depositing thin films and a method of manufacturing a memory device including the same. More specifically, it relates to a method of depositing thin films using a metal precursor containing a halogen group and an organic ligand, and a method of manufacturing a memory device including the same.

### BACKGROUND

In the field of semiconductor processing, deposition processes are important for depositing materials on substrates. As electronic devices continue to shrink in size and increase in density, the aspect ratios of features are increasing. Therefore, processes with good step coverage are gaining attention, particularly atomic layer deposition (ALD).

Currently, DRAM in the memory field and logic memory in the non-memory field have reached physical limits, making it difficult to form uniform thin films even with ALD. To overcome this limitation, there is an increasing need to form thin films with uniform thickness on three-dimensional structures with very high aspect ratios.

Metal halides are widely used as precursors for forming metal thin films due to their low cost, good reactivity, and thermal stability. However, they are often solid at room temperature, making them difficult to use in deposition processes. They also require high-temperature deposition processes and can produce unwanted etching due to halogen ions as byproducts, making thickness control difficult.

Organometallic compounds are most commonly used as ALD precursors due to their non-toxicity and high volatility. Ideal ALD involves the formation of a single atomic layer through self-limiting surface reactions during repeated precursor supply and removal cycles. However, in actual ALD processes using organometallic compounds, it is very difficult to achieve self-limiting surface reactions due to multilayer formation from intermolecular forces and decomposition of thermally unstable organic ligands.

Therefore, it typically takes a long time to optimize process conditions to address these issues.

An object of the present invention is to provide a method of depositing thin films that enables ideal ALD implementation through the use of hybrid precursors containing at least one halogen group and an organic ligand, allowing easy thickness control and greatly improved step coverage, and a method of manufacturing a memory device including the same.

Another object of the present invention is to provide a method of depositing thin films that can minimize contamination within the thin film due to halogens, and a method of manufacturing a memory device including the same.

Other objects of the present invention will become more apparent from the following detailed description.

### SUMMARY

Disclosed is a method of depositing thin films, the method comprising supplying a metal precursor to the inside of a chamber where a substrate is placed to adsorb the metal precursor onto the substrate; purging the inside of the chamber; supplying a reactant to the inside of the chamber to react with the adsorbed metal precursor and form a thin film, wherein the metal precursor includes one or more halogen groups and one or more organic ligands.

The metal precursor may be represented by the following Chemical Formula 1:

Al(L)ₙ(X)₃₋ₙ <Chemical Formula 1>
in Chemical Formula 1, n is independently selected from integers of 1 to 2,
X is selected from halogen elements,
L is independently the same or different, and selected from hydrogen atom, linear, branched, or cyclic alkyl groups having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, aralkyl groups having 7 to 13 carbon atoms,
L includes a bidentate organic ligand bonded with N, O, P, S elements.

The metal precursor may be represented by the following Chemical Formula 2:

Ti(L)ₙ(X)₄₋ₙ <Chemical Formula 2>
in Chemical Formula 2, n is independently selected from integers of 1 to 3,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

The metal precursor may be represented by the following Chemical Formula 3 to Chemical Formula 5:

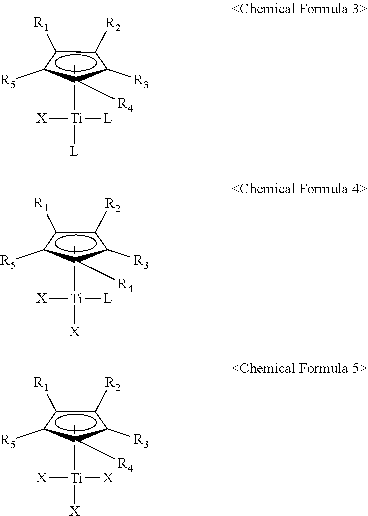

in Chemical Formula 3 to Chemical Formula 5, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

The metal precursor may be represented by the following Chemical Formula 6:

Nb(L)ₙ(X)₅₋ₙ <Chemical Formula 6>
in Chemical Formula 6, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

The metal precursor may be represented by the following Chemical Formula 7 to Chemical Formula 9:

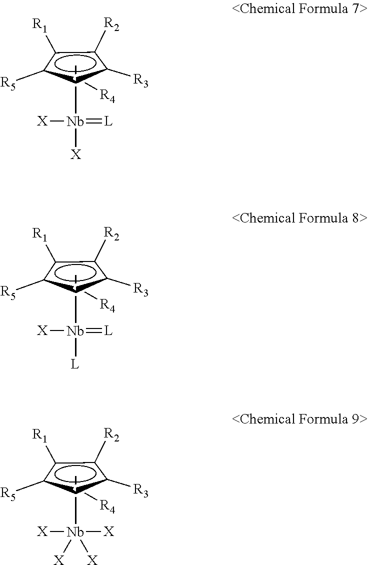

in Chemical Formula 7 to Chemical Formula 9, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

The metal precursor may be represented by the following Chemical Formula 10:

Ta(L)ₙ(X)₅₋ₙ <Chemical Formula 10>
in Chemical Formula 10, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

The method may be carried out at 50 to 700° C.

The thin film may be one of a metal film, metal oxide, metal nitride, or metal sulfide.

Disclosed is a method of manufacturing a volatile memory device may include the aforementioned method of depositing thin films.

Disclosed is a method of manufacturing a non-volatile memory device may include the aforementioned method of depositing thin films.

### BRIEF DESCRIPTION OF THE DRAWINGS

FIG. 1 is a graph schematically showing a supply cycle according to an embodiment of the present invention.

FIG. 2 is a schematic diagram showing the adsorption process of the metal precursor according to an embodiment of the present invention.

FIG. 3 is a schematic diagram showing the adsorption process of the metal precursor in 3D structures such as holes, trenches, and gap features formed on the substrate according to an embodiment of the present invention.

FIG. 4 is a graph showing essential characteristics of ALD and a graph comparing growth rates under conditions of increasing the amount of tantalum chloride input for example and comparative example of the present invention.

FIG. 5 is a graph schematically showing a supply cycle in an experiment to confirm the self-etching phenomenon according to an embodiment of the present invention.

FIG. 6 shows the results of confirming step coverage by depositing a niobium oxide film on a patterned wafer according to an embodiment of the present invention.

### DETAILED DESCRIPTION

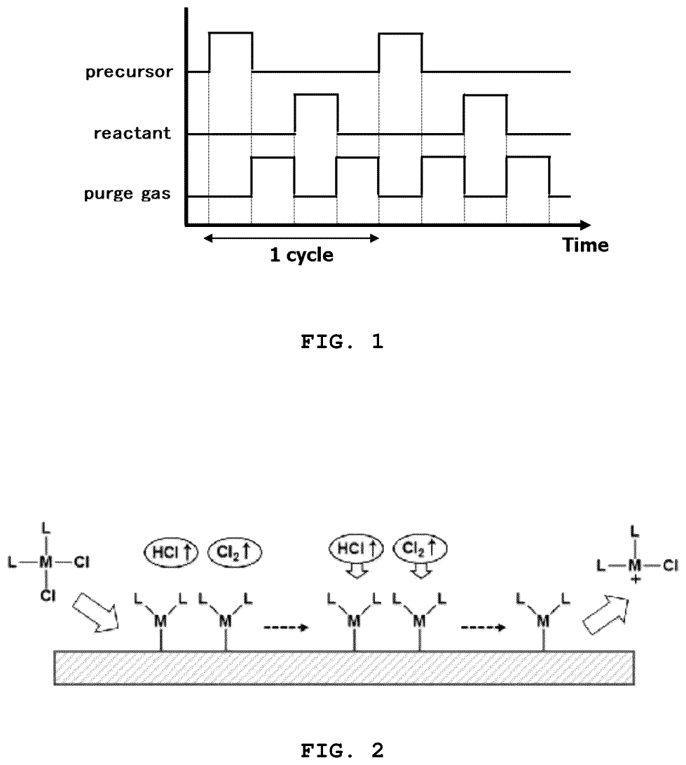

Hereinafter, embodiments of the present invention will be described with reference to FIGS. 1 to 6. The embodiments of the present invention can be modified in various forms, and the scope of the present invention should not be interpreted as being limited to the embodiments described below.

FIG. 1 is a graph schematically showing a supply cycle according to an embodiment of the present invention. A substrate is loaded into a process chamber, and the following ALD process conditions are adjusted. The process conditions may include a temperature of the substrate or process chamber, a pressure in the process chamber, gas flow rate, and the temperature is 50 to 700° C.

The substrate is exposed to the metal precursor supplied to the inside of the chamber, and the metal precursor is adsorbed to the surface of the substrate. At this time, the metal precursor is supplied at 50 to 700° C.

Specifically, the metal precursor may be represented by the following Chemical Formula 1:

Al(L)ₙ(X)₃₋ₙ <Chemical Formula 1>
in Chemical Formula 1, n is independently selected from integers of 1 to 2,
X is selected from halogen elements,
L is independently the same or different, and selected from hydrogen atom, linear, branched, or cyclic alkyl groups having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, aralkyl groups having 7 to 13 carbon atoms,
L includes a bidentate organic ligand bonded with N, O, P, S elements.

Also, the metal precursor may be represented by the following Chemical Formula 2:

Ti(L)ₙ(X)₄₋ₙ <Chemical Formula 2>
in Chemical Formula 2, n is independently selected from integers of 1 to 3,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

Also, The metal precursor may be represented by the following Chemical Formula 3 to Chemical Formula 5:

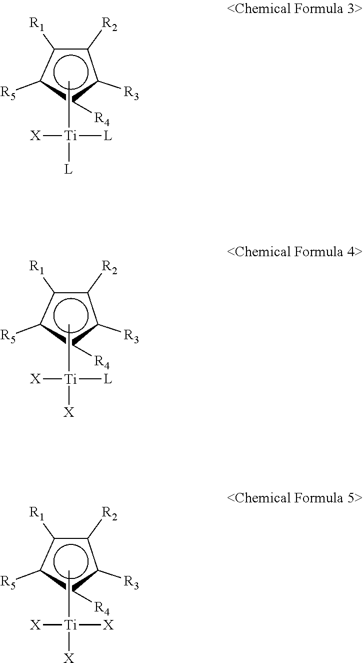

in Chemical Formula 3 to Chemical Formula 5, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

Also, the metal precursor may be represented by the following Chemical Formula 6:

Nb(L)ₙ(X)₅₋ₙ <Chemical Formula 6>
in Chemical Formula 6, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

Also, the metal precursor may be represented by the following Chemical Formula 7 to Chemical Formula 9:

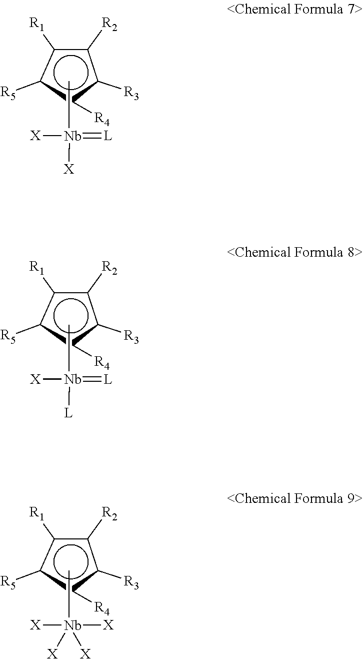

in Chemical Formula 7 to Chemical Formula 9, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

Also, the metal precursor may be represented by the following Chemical Formula 10:

Ta(L)ₙ(X)₅₋ₙ <Chemical Formula 10>
in Chemical Formula 10, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

The above-mentioned bidentate organic ligand means ethylenediamine, bipyridyl, acetylacetonate, oxalate, sulfonamide, bis(dimethylphosphino) ethane, etc., but is not limited thereto.

FIG. 2 is a schematic diagram showing the adsorption process of the metal precursor according to an embodiment of the present invention. The metal precursor can generate corrosive gas and halogen ions during the adsorption process, similar to conventional metal halides. The generated halogen ions can be re-adsorbed on the surface, exhibiting a self-etching effect that volatilizes some of the adsorbed metal precursors, which can be interpreted as resulting in a low deposition rate.

The metal precursor according to embodiments of the presen invention has fewer halogen ligands compared to conventional metal halides, preventing excessive etching, and large organic ligands like cyclopentadiene inhibit halogen substitution, allowing stable thin film formation.

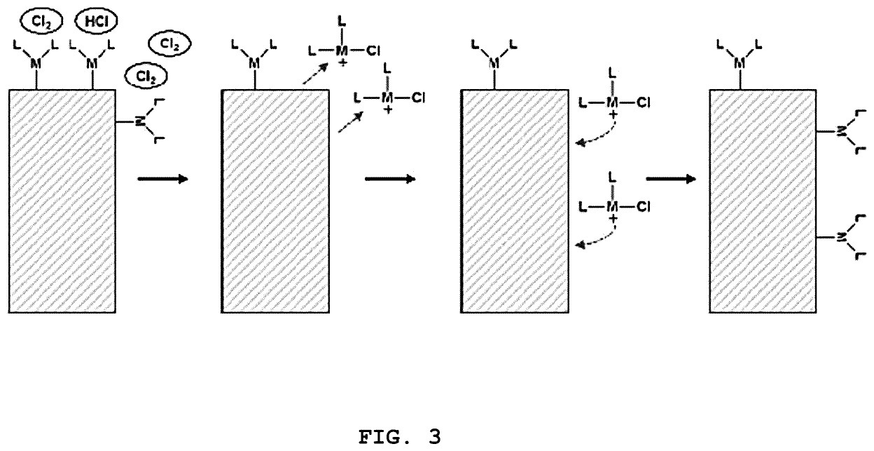

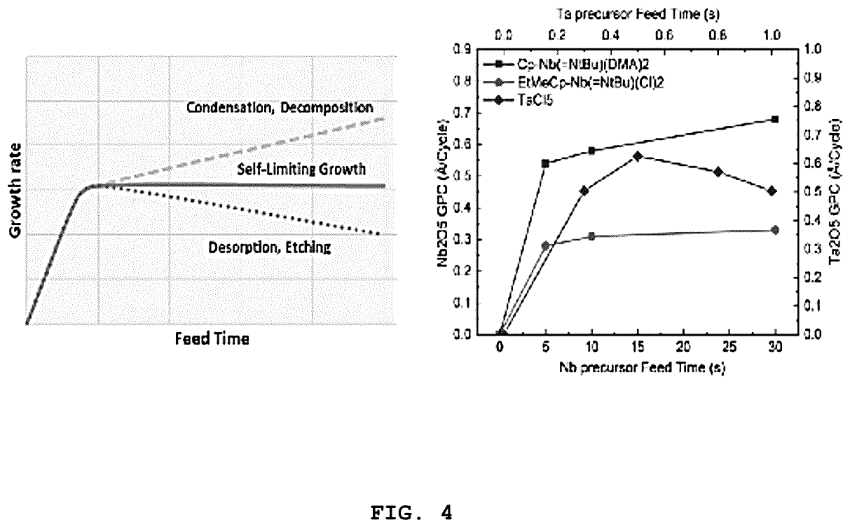

FIG. 3 is a schematic diagram showing the adsorption process of the metal precursor in 3D structures such as holes, trenches, and gap features formed on the substrate according to an embodiment of the present invention.

First, the metal precursor is adsorbed at high density on the upper part of the structure, generating corrosive gas and halogen ions during adsorption. Next, the generated halogen ions are re-adsorbed on the surface, volatilizing some of the adsorbed metal precursors. Then, the volatilized metal precursors diffuse downward through a cascading effect, acting as secondary metal precursor. Finally, the secondary metal precursor diffused downward are adsorbed, forming a conformal thin film.

Thereafter, a purge gas (for example, an inert gas such as Ar) is supplied to the inside of the chamber to discharge the unadsorbed metal precursorr or by-products.

Thereafter, the substrate is exposed to a reactant supplied to the inside of the chamber to form a thin flim. The reactant reacts with the metal precursor layer to form a thin film, the thin film may be one of a metal film, metal oxide, metal nitride, or metal sulfide. The thin film is formed at 50 to 700° C.

Thereafter, a purge gas (for example, an inert gas such as Ar) is supplied to the inside of the chamber to discharge the unreacted substances or by-products.

### Deposition Rate

### Comparative Example

A niobium oxide film was formed on the silicon substrate, using Cp-Nb=NtBu (DMA) 2 as a precursor. The niobium oxide film was formed through the ALD process, the process temperature was 250° C. to 350° C., and the reactant was O₃ gas.

The process of forming the niobium oxide film through the ALD process is as follows, and the following process is performed as one cycle.

1) Ar is used as a carrier gas, the niobium precursor Cp-Nb=NtBu (DMA)2 is supplied to the reaction chamber at room temperature, and the niobium precursor is adsorbed onto the substrate.

2) Ar gas is supplied into the reaction chamber to discharge unadsorbed niobium precursors or byproducts.

3) monolayer is formed by supplying O₃ gas to the reaction chamber.

4) Ar gas is supplied into the reaction chamber to discharge unreacted substances or by-products.

As a result of measuring the thickness of the niobium oxide film obtained by the above-mentioned process, the growth rate of the niobium oxide film obtained per cycle of the ALD process was confirmed to be approximately 0.6 Å/cycle at 300° C.

### Example

A niobium oxide film was formed on the silicon substrate, using EtMeCp-Nb=NtBu(Cl)2 as a precursor. The niobium oxide film was formed through the ALD process, the process temperature was 250° C. to 350° C., and the reactant was O₃ gas. Except for changing the metal precursor to EtMeCp-Nb=NtBu(Cl)2, the niobium oxide film was formed in the same manner as in the comparative example.

As a result of measuring the thickness of the niobium oxide film obtained by the above-mentioned process, the growth rate of the niobium oxide film obtained per cycle of the ALD process was confirmed to be approximately 0.25 Å/cycle at 250 to 300° C. Compared to the comparative example, it can be confirmed that the growth rate of the thin film is low and the thin film growth rate is maintained constant over a wide temperature range.

### <Increasing Feed Time>

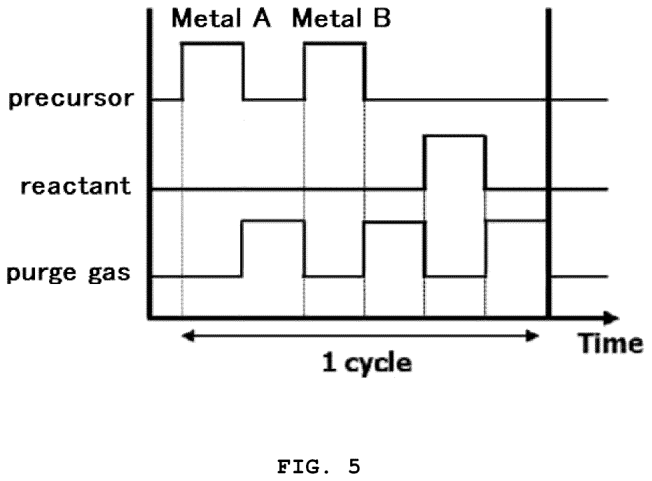

FIG. 4 is a graph showing essential characteristics of ALD and a graph comparing growth rates under conditions of increasing the amount of tantalum chloride input for example and comparative example of the present invention.

As shown in the left graph of FIG. 4, the ideal ALD requires saturation in the growth per cycle according to the feed time, which means that self-limiting deposition is possible for each cycle.

As shown in the right graph of FIG. 4, tantalum chloride is a compound with representative etching characteristics, and it tends to decrease in growth rate as input increases. While the comparative example (organic ligand compound) shows a continuous increase with increasing input (18% increase in growth rate), the example maintains a constant growth rate even with increased input, demonstrating good saturation characteristics (6% increase in growth rate). It can be inferred that the growth rate is constant due to a self-limiting reaction in a precursor compound containing both halogen and organic ligand, and thus a conformal thin film is formed even in a three-dimensional structure.

### <Self-Etching Phenomenon>

FIG. 5 is a graph schematically showing a supply cycle in an experiment to confirm the self-etching phenomenon according to an embodiment of the present invention.

On a Si substrate, an oxide film was formed using EtMeCp-Nb=NtBu(Cl)2 (represented as <Chemical Formula 11> below, Metal A), a metal precursor according to the example, and EtMeCp-Ta=NtBu(Cl)2 (represented as <Chemical Formula 12> below, Metal B), a tantalum compound having the same ligand and belonging to the same group in the periodic table as the metal compound of the example. As shown in a supply cycle in FIG. 5, metal A and metal B were sequentially supplied, and then the metal oxide film was formed through the ALD process that forms the oxide film. The process temperature was 320° C., and the reactant was O₃ gas.

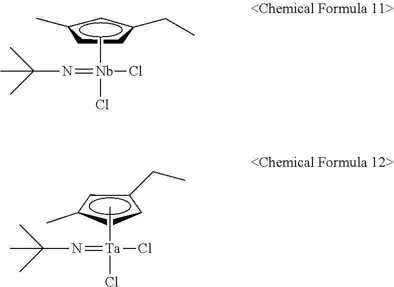

Table 1 below shows the results of comparative analysis of the metal content of the formed thin film using XPS (X-ray photoelectron spectroscopy).

TABLE 1

| | ALD Time (sec) | | | | | | | | |
|---|---|---|---|---|---|---|---|---|---|
| Exper- | Metal A | | Metal B | | O₃ | | | | |
| iment | Feed | Purge | Feed | Purge | Feed | Purge | Cycle | Nb % | Ta % |
| Exper- | 3 | 15 | 0 | 0 | 3 | 15 | 100 | 24.1% | — |
| iment#1 | | | | | | | | | |
| Exper- | 3 | 15 | 3 | 15 | 3 | 15 | 100 | 19.8% | 7.0% |
| iment#2 | | | | | | | | | |
| Exper- | 3 | 15 | 10 | 15 | 3 | 15 | 100 | 15.7% | 9.6% |
| iment#3 | | | | | | | | | |

As described in [Table 1] above, when only EtMeCp-Nb=NtBu(Cl)2 was used to perform 100 cycles of the process, the Nb % in the thin film was confirmed to be 24.1% (Experiment #1). When EtMeCp-Nb=NtBu(Cl)2 was supplied at the same time and then EtMeCp-Ta=NtBu(Cl)2 was supplied, it was confirmed that the Nb % in the thin film decreased to 19.8% and the Ta % in the thin film increased to 7.0% (Experiment 2). When the tantalum compound supply time was increased and the same process was performed, it was confirmed that the Nb % in the thin film further decreased and the Ta % in the thin film further increased (Experiment 3).

The above-mentioned results can be interpreted that the niobium compound adsorbed on the surface during the precursor supply process was etched and the supplied tantalum compound was deposited. When only the niobium compound of the present invention is used, it can be inferred that etching occurs by itself during the surface adsorption process.

As explained with respect to FIG. 3, the secondary metal precursor generated by the self-etching phenomenon can diffuse downward and ultimately form a conformal thin film.

### <Step Coverage>

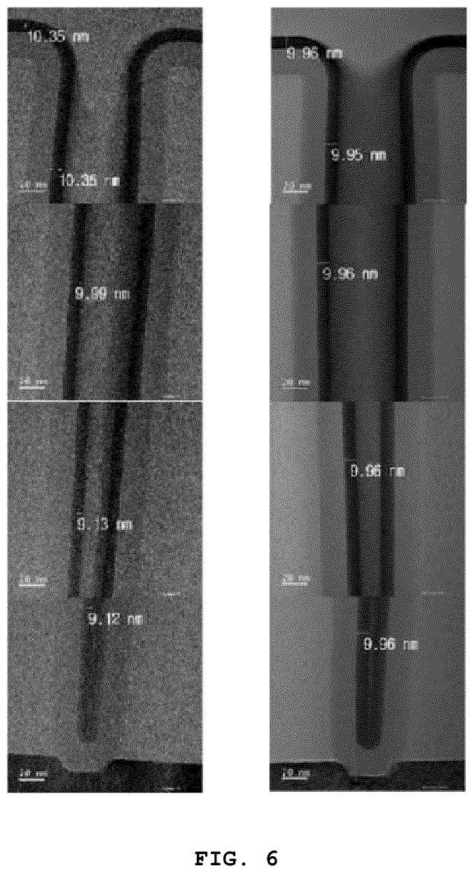

FIG. 6 shows the results of confirming step coverage by depositing a niobium oxide film on a patterned wafer according to an embodiment of the present invention.

### Comparative Example

As a result of confirming the step coverage by depositing the niobium oxide film according to the comparative example on a pattern wafer with an aspect ratio of 40:1 at a process temperature of 320° C., the top thickness of the thin film obtained under the same process conditions was 10.35 nm, the bottom thickness was 9.12 nm, and the step coverage was 88% (left side of FIG. 6).

### Example

As a result of confirming the step coverage by depositing the niobium oxide film according to the example on a pattern wafer with an aspect ratio of 40:1 at a process temperature of 320° C., the top thickness of the thin film obtained under the same process conditions was 9.95 nm, the bottom thickness was 9.96 nm, and the step coverage was 100% (right side of FIG. 6).

Table 2 below shows the results according to comparative example and example.

TABLE 2

| | | ALD Time (sec) | | | | |
|---|---|---|---|---|---|---|
| | Process | Source | | O3 | | Step |
| Precursor | temperature | Feed | Purge | Feed | Purge | Coverage |
| Comparative | 300° C. | 10 | 30 | 10 | 30 | 88% |
| example | | | | | | |
| Example | 320° C. | 10 | 30 | 10 | 30 | 100% |

According to embodiments of the present invention, thin films having good step coverage can be formed. In particular, the deposition rate is maintained constant, making it easy to control the thickness of the thin films

The present invention has been explained in detail with reference to embodiments, but other embodiments may be included. Accordingly, the technical idea and scope described in the claims below are not limited to the embodiments.

1. A method of depositing thin films, the method comprising:
supplying a metal precursor to the inside of a chamber where a substrate is placed to adsorb the metal precursor onto the substrate;
purging the inside of the chamber; and
supplying a reactant to the inside of the chamber to react with the adsorbed metal precursor and form a thin film,
wherein the metal precursor includes one or more halogen groups and one or more organic ligands.

2. The method of claim 1, wherein the metal precursor is represented by the following Chemical Formula 1:
Al(L)ₙ(X)₃₋ₙ <Chemical Formula 1>
in Chemical Formula 1, n is independently selected from integers of 1 to 2,
X is selected from halogen elements,
L is independently the same or different, and selected from hydrogen atom, linear, branched, or cyclic alkyl groups having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, aralkyl groups having 7 to 13 carbon atoms,
L includes a bidentate organic ligand bonded with N, O, P, S elements.

3. The method of claim 1, wherein the metal precursor is represented by the following Chemical Formula 2:
Ti(L)ₙ(X)₄₋ₙ <Chemical Formula 2>
in Chemical Formula 2, n is independently selected from integers of 1 to 3,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

4. The method of claim 1, wherein the metal precursor is represented by the following Chemical Formula 3 to Chemical Formula 5: 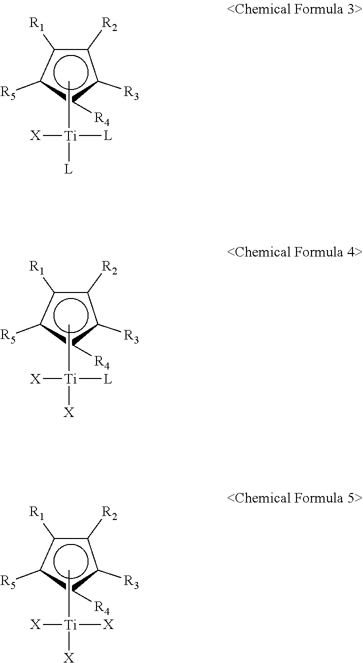
in Chemical Formula 3 to Chemical Formula 5, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

5. The method of claim 1, the metal precursor is represented by the following Chemical Formula 6:
Nb(L)ₙ(X)₅₋ₙ <Chemical Formula 6>
in Chemical Formula 6, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

6. The method of claim 1, wherein the metal precursor is represented by the following Chemical Formula 7 to Chemical Formula 9: 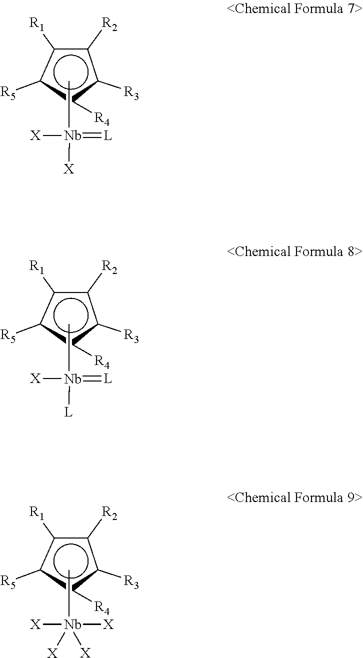
in Chemical Formula 7 to Chemical Formula 9, R1 to R5 are each independently selected from hydrogen, linear, branched or cyclic alkyl groups having 1 to 5 carbon atoms, alkoxy groups having 1 to 5 carbon atoms, and phenyl groups having 6 to 12 carbon atoms,
X is selected from halogen elements,
L is independently the same or different, and selected from hydrogen atom, linear, branched or cyclic alkyl group having 1 to 10 carbon atoms, alkoxy groups having 1 to 5 carbon atoms, amino groups having 1 to 5 carbon atoms, dialkylamino groups having 1 to 5 carbon atoms, aryl groups having 6 to 12 carbon atoms, and aralkyl groups having 7 to 13 carbon atoms,
L includes a bidentate organic ligand bonded to an element of N, O, P, or S.

7. The method of claim 1, wherein the metal precursor is represented by the following Chemical Formula 10:
Ta(L)ₙ(X)₅₋ₙ <Chemical Formula 10>
in Chemical Formula 10, n is independently selected from integers of 1 to 4,
X is selected from halogen elements,
L is independently the same or different, and selected from hydrogen atom, linear, branched, or cyclic alkyl groups having 1 to 10 carbon atoms, cyclopentadienyl group, substituted alkyl cyclopentadienyl group, alkoxy groups having 1 to 5 carbon atoms, amino groups having 1 to 5 carbon atoms, dialkylamino groups having 1 to 5 carbon atoms, alkylimido groups having 1 to 5 carbon atoms, aryl groups having 6 to 12 carbon atoms, aralkyl groups having 7 to 13 carbon atoms,
L includes a bidentate organic ligand bonded with N, O, P, S elements.

8. The method of claim 1, wherein the method is carried out at 50 to 700° C.

9. The method of claim 1, wherein the thin film is one of a metal film, metal oxide, metal nitride, or metal sulfide.

10. A method of manufacturing a volatile memory device, the method comprising the method of depositing thin films according to claim 1.

11. A method of manufacturing a non-volatile memory device, the method comprising the method of depositing thin films according to claim 1.
